(19) United States
(12) Patent Application Publication
(10) Pub. No.: US 2022/0417671 A1
(43) Pub. Date: Dec. 29, 2022

(54) MEMS Acoustic Sensor

(71) Applicant: AAC Kaitai Technologies (Wuhan) CO., LTD, Wuhan (CN)

(72) Inventors: Qiang Dan, Shenzhen (CN); Yiwei Zhou, Shenzhen (CN); Shiyang Cheng, Shenzhen (CN); Yang Li, Shenzhen (CN)

(21) Appl. No.: 17/566,688

(22) Filed: Dec. 31, 2021

(30) Foreign Application Priority Data
Jun. 28, 2021 (CN) 202121452074.0

(51) Int. Cl. H04R 19/04; H04R 7/06; B81B 3/00; H04R 17/02; H04R 7/18

(52) U.S. Cl. CPC H04R 19/04; H04R 7/06; B81B 3/0037; H04R 17/02; H04R 7/18; B81B 2201/0257; B81B 2203/0127; H04R 2201/003; B81B 2203/0315

(57) ABSTRACT

One of the main objects of the present invention is to provide a MEMS acoustic sensor with improved acoustic performance and liability. To achieve the above-mentioned objects, the present invention provides a MEMS acoustic sensor, including: a base with a cavity; a number of structural layers fixed on the base, each including a fixed end fixed to the base and a suspension end extending from the fixed end for being suspended above the cavity, the suspension end being spaced from the base for forming a slit; a piezoelectric functional layer on the suspension end; and a flexible connector completely covering the slit; wherein a Young's modulus of the flexible connector is smaller than a Young's modulus of the structural layer.

### FIELD OF THE PRESENT DISCLOSURE

The present invention relates to electromechanical transducers, and more particularly to a MEMS acoustic sensor.

### DESCRIPTION OF RELATED ART

Acoustic sensors, as one of the main components of mobile terminals such as mobile phones, are mainly used to convert electrical signals into sound signals.

The MEMS acoustic sensor (micro-electro-mechanical system), that is, micro-electro-mechanical system acoustic sensor. Compared with traditional voice coil speakers, it has the advantages of good consistency, low power consumption, small size, and low price. Mainly include planar and three-dimensional structures. In the planar architecture, the driver and the vibration sounding assembly are coupled together. In related technologies, a planar MEMS acoustic sensor usually includes a base, a diaphragm fixed on the base, and a piezoelectric functional layer fixed on the diaphragm. The piezoelectric functional layer deforms after being energized, which drives the diaphragm to vibrate and produce sound.

However, in the MEMS acoustic sensor of the related art, the piezoelectric functional layer includes a piezoelectric plate and an electrode layer provided on the lower surface of the piezoelectric plate. The diaphragm vibrates due to the deformation of the piezoelectric plate and forms a first area fixed to the piezoelectric functional layer and a second area spaced apart. The MEMS acoustic sensor also includes a polymer layer formed on the electrode layer. The Young's modulus of the polymer layer is smaller than the Young's modulus of the piezoelectric plate, which makes the area range of the piezoelectric functional layer in the related art completely restricted to the cavity range of the base. The area of the diaphragm that can drive vibration is also limited, resulting in the inability to further improve the acoustic performance of the MEMS acoustic sensor.

Therefore, it is necessary to provide a new MEMS acoustic sensor to solve the above technical problems.

### SUMMARY OF THE PRESENT DISCLOSURE

One of the main objects of the present invention is to provide a MEMS acoustic sensor with improved acoustic performance and liability.

To achieve the above-mentioned objects, the present invention provides a MEMS acoustic sensor, including: a base with a cavity; a plurality of structural layers fixed on the base, each including a fixed end fixed to the base and a suspension end extending from the fixed end for being suspended above the cavity, the suspension end being spaced from the base for forming a slit; a piezoelectric functional layer on the suspension end; and a flexible connector completely covering the slit; wherein a Young's modulus of the flexible connector is smaller than a Young's modulus of the structural layer.

In addition, the fixed end is fixed to one side of the base along a long axis or along a short axis; the suspension end is oppositely spaced from the other three sides of the base to form the slit; the flexible connector connects the suspension end and the base and completely covers the slit.

In addition, an amount of the structural layer is two; the fixed end is fixed on each side of the base opposite to each other; the two suspension ends extend oppositely and are spaced apart from each other; the suspension end is oppositely spaced from the base to form a first slit, and the suspension end is oppositely spaced to form a second slit; the first slit is in communication with the second slit.

In addition, the flexible connector includes a first connector that completely covers the first slit and a second connector that completely covers the second slit; the first connector connects the suspension end and the base; the second connector connects the two adjacent suspension ends; the first connector and the second connector are connected with each other.

In addition, an amount of the structural layer is four; the fixed end is fixed on each side of the base; the four suspension ends are arranged at intervals; the slit extends along two diagonals of the base.

In addition, the structural layer is fixed to the base along one side of the hypotenuse to form the fixed end; the right-angle tips of the four structural layers are oppositely spaced apart.

In addition, the MEMS acoustic sensor further includes a weight accommodated in the cavity and being apart from the base; the base and the weight are concentric rectangles; four structural layers are arranged; one fixing part is fixed on each side of the base; the suspension end extends from the fixing portion toward the weight to be spaced apart from the weight; the slit includes a second slit formed by two adjacent suspension ends and a third slit between the suspension end and the weight; the second slit extends from the corner position of the weight to the corner position of the base.

In addition, the flexible connector includes a second connector covering the second slit and a third connector covering the third slit; the four third connectors are connected end to end to form a ring-shaped rectangle; the second connector is fixed at the junction of two adjacent third connectors.

In addition, the flexible connector is in the shape of a flat plate.

In addition, the flexible connector includes a first fixed part fixed to the base, a second fixed part fixed to the suspension end, and an flexible part connecting the first fixed part and the second fixed part; the section of the flexible part along the vibration direction of the structural layer is arc, triangle, or rectangle; the structural layer further includes an flexible connection structure that extends from the end of the suspension end away from the fixed end to the weight to be fixed to the weight; the flexible connection structure is located at both ends of the suspension end close to the second slit.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is an isometric view of a MEMS acoustic sensor in accordance with Embodiment 1 of the present invention;

FIG. 2 is a cross-sectional view of the MEMS acoustic sensor of Embodiment 1;

FIG. 3 is an isometric view of a MEMS acoustic sensor in accordance with Embodiment 2 of the present invention;

FIG. 4 is a cross-sectional view of the MEMS acoustic sensor in Embodiment 2;

FIG. 5 is a cross-sectional view of the MEMS acoustic sensor in Embodiment 2;

FIG. 6 is an isometric view of a MEMS acoustic sensor in accordance with Embodiment 3 of the present invention;

FIG. 7 is an isometric view of a MEMS acoustic sensor in accordance with Embodiment 3 of the present invention;

FIG. 8 is an isometric view of a MEMS acoustic sensor in accordance with Embodiment 4 of the present invention;

FIG. 9 is a cross-sectional view of the MEMS acoustic sensor in Embodiment 4;

FIG. 10 is a bottom view of the MEMS acoustic sensor in Embodiment 4;

FIG. 11 is an isometric view of a MEMS acoustic sensor in accordance with Embodiment 5 of the present invention;

FIG. 12 is an exploded view of the MEMS acoustic sensor in Embodiment 5.

### DETAILED DESCRIPTION OF THE EXEMPLARY EMBODIMENTS

The present disclosure will hereinafter be described in detail with reference to several exemplary embodiments. To make the technical problems solved, technical solutions and beneficial effects of the present disclosure more apparent, the present disclosure is described in further detail together with the figures and the embodiments. It should be understood the specific embodiments described hereby are only to explain the disclosure, not intended to limit the disclosure.

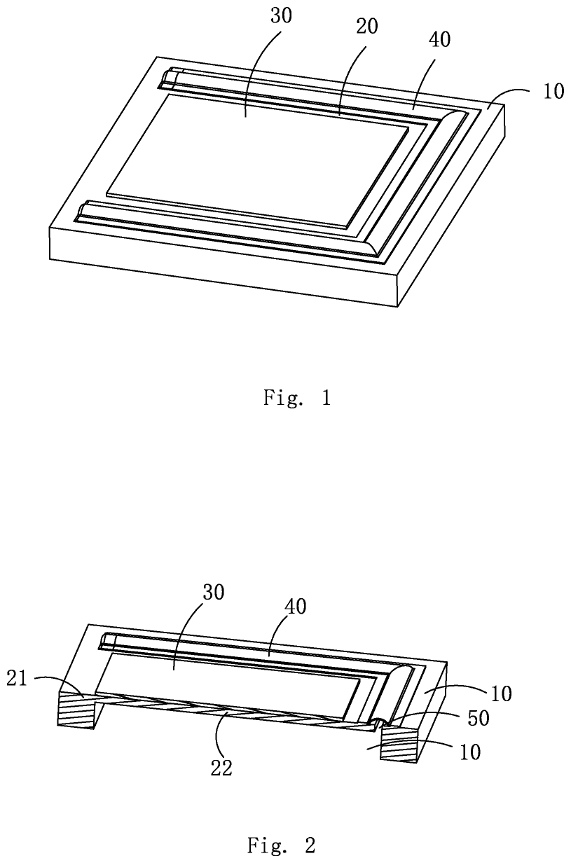

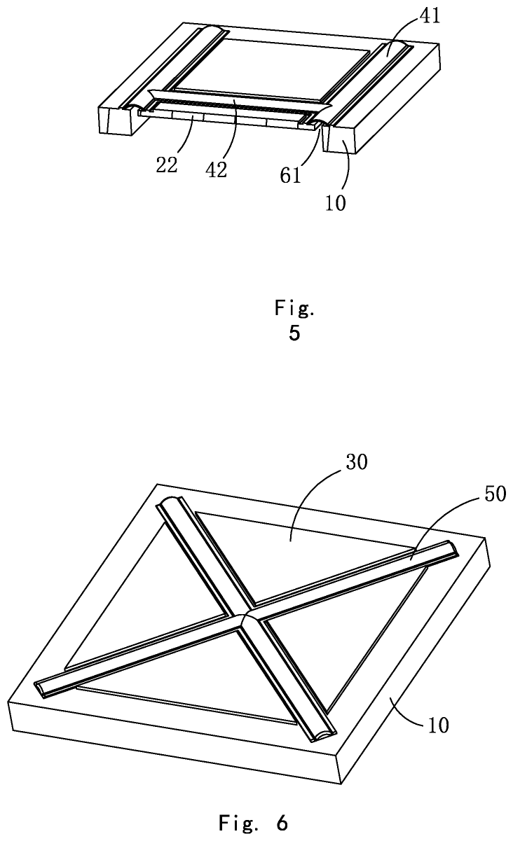

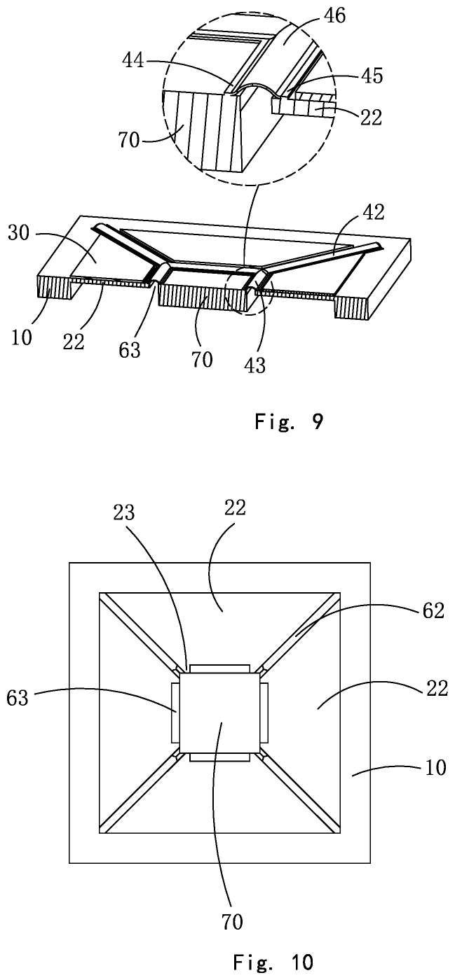

Please refer to FIG. 1 to FIG. 12 at the same time. This embodiment provides an MEMS acoustic sensor, which includes a base 10 with a cavity 11, a structural layer 20 fixed on the base, and a piezoelectric functional layer 30 fixed on the structural layer 20, and an flexible connector 40.

The structural layer 20 includes a fixed end 21 fixed to the base 10 and a suspension end 22 extending from the fixed end 21 to suspended above the cavity 11. The piezoelectric functional layer 30 is provided on the suspension end 22. The piezoelectric functional layer 30 deforms after being energized to drive the structural layer 20 to vibrate. The number of structural layer 20 can be one, two, three or more. The interval between suspension end 22 and base 10 or between suspension end 22 is covered by flexible connector 40. And in order to make the piezoelectric functional layer 30 better drive the structural layer 20 to vibrate, the Young's modulus of the flexible connector 40 is smaller than the Young's modulus of the structural layer 20. The structure of MEMS acoustic sensor with different number of structural layer 20 (that is, different number of suspension end 22) will be described in detail below.

### Embodiment 1

As shown in FIG. 1 to FIG. 2, the number of structural layer 20 of the MEMS acoustic sensor in embodiment 1 is one, and base 10 is rectangular. The fixed end 21 of the structural layer 20 is fixed to one side of the base 10 along the short axis direction. Suspension end 22 is spaced apart from the other three sides of base 10 to form a slit 50. The flexible connector 40 and the piezoelectric functional layer 30 are arranged at intervals. And the flexible connector 40 completely covers the slit 50. Specifically, one side of the flexible connector 40 is connected to the suspension end 22, and one side is connected to the base 10, so as to completely cover the slit 50. The MEMS acoustic sensor has no air leakage area, ensuring good acoustic performance. It should be understood that the Young's modulus of the flexible connector 40 is smaller than the Young's modulus of the structural layer 20.

### Embodiment 2

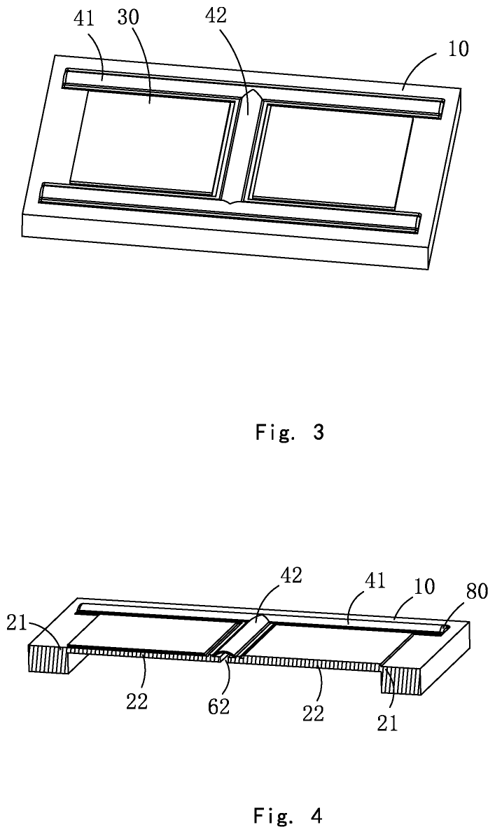

As shown in FIG. 3-FIG. 5, the number of structural layer 20 in embodiment 2 is two. The base 10 is a rectangle, and the two sides of the base 10 are fixed with a fixed end 21. The two suspension ends 22 extend oppositely and are spaced apart from each other. The suspension end 22 and the base 10 are oppositely spaced to form a first slit 61. The two suspension ends 22 are oppositely spaced apart to form a second slit 62. The first slit 61 is connected to the second slit 62. As can be seen in the figure, the structural layer 20 is fixed to the side of the base 10 along the short axis direction.

The suspension end 22 and the base 10 are separated from the side along the long axis to form a first slit 61. The second slit 62 formed by the two suspension ends 22 is parallel to the side of the base 10 along the minor axis. And two first slits 61 are arranged, which are connected with the second slit 62 to form an h-shaped slit. Correspondingly, the flexible connector 40 includes a first connector 41 that completely covers the first slit 61 and a second connector 4 that completely covers the second slit 62. The first connector 41 connects the suspension end 22 and base 10. The second connector 42 is connected to two adjacent suspension ends 22, and the first connector 41 and the second connector 42 are connected and arranged. It is also correspondingly formed to have an h shape to completely seal the first slit 61 and the second slit 62.

### Embodiment 3

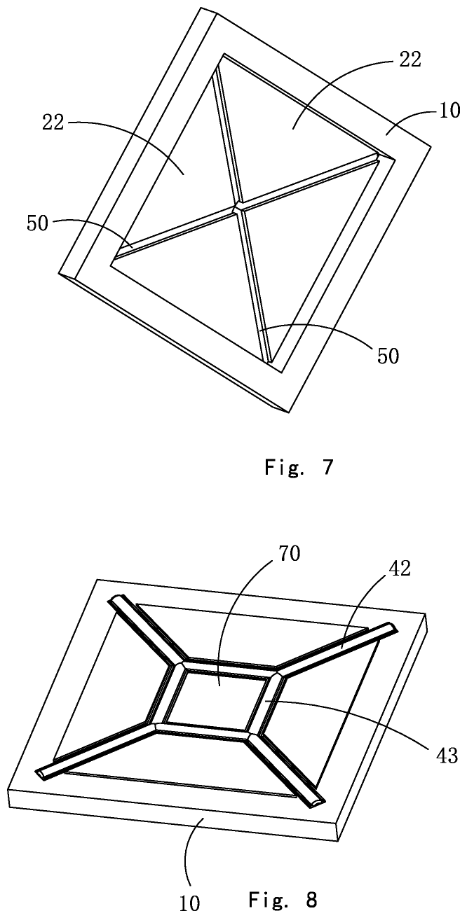

As shown in FIGS. 6-7, the suspension ends 22 in embodiment 3 are four and all are triangular, the corresponding piezoelectric functional layer 30 is also triangular, the base 10 is still rectangular, and the four suspension ends 22 are spaced apart from each other. The slit 50 extends along the two diagonals of the base 10. Specifically, the structural layer 20 has a right-angled triangle shape. Therefore, the hypotenuse edge of structural layer 20 is fixed to base 10. The right-angle tips of the four structural layers 20 are oppositely spaced apart. The right-angle sides of two adjacent suspension ends 22 are arranged at intervals. Thus, two slit 50 extending along the diagonal of base 10 are formed. And the intersection of the two slits 50 is opposite to the right-angled tips of the four suspension ends 22 at an interval. Correspondingly, the flexible connector 40 completely covers the two slits 50.

### Embodiment 4

As shown in FIGS. 8-10, the MEMS acoustic sensor also includes a weight 70 accommodated in the 11 cavity and spaced from the base 10. Base 10 and weight 70 are concentric rectangles. Four structural layers 20 are arranged, and the suspension end 22 extends toward the weight 70 to be spaced apart from the weight 70. The slit 50 includes a second slit 62 formed by two adjacent suspension ends 22 and a third slit 63 between the suspension end 22 and the weight 70. The second slit 62 extends from the corner position of weight 70 to the corner position of base 10.

It is understandable the number of the second slit 62 is four and the number of the third slit 63 is also four. Correspondingly, the flexible connector 40 includes a second connector 62 covering the second slit 62 and a third connector 43 covering the third slit 63. Four third connectors 43 are connected end to end to form a ring-shaped rectangle, and the second connector 42 is fixed at the junction of two adjacent third connectors 42. That is, the second connector 42 is fixed at the apex of the ring-shaped rectangle enclosed by the third connector 42. The flexible connector 40 includes a first fixed part 44 fixed to the weight 70, a second fixed part 45 fixed to the suspension end 22, and an flexible part 46 connecting the first fixed part 44 and the second fixed part 45. The cross section of the flexible part 46 along the vibration direction of the structural layer 20 is arc, triangle, or rectangle.

The structural layer 20 also includes a flexible connection structure 23 that extends from the end of the suspension end 22 away from the base 10 to the weight 70 to be fixed to the weight 70. The flexible connection structure 23 is located at the ends of the suspension end 22 close to the second slit 62.

### Embodiment 5

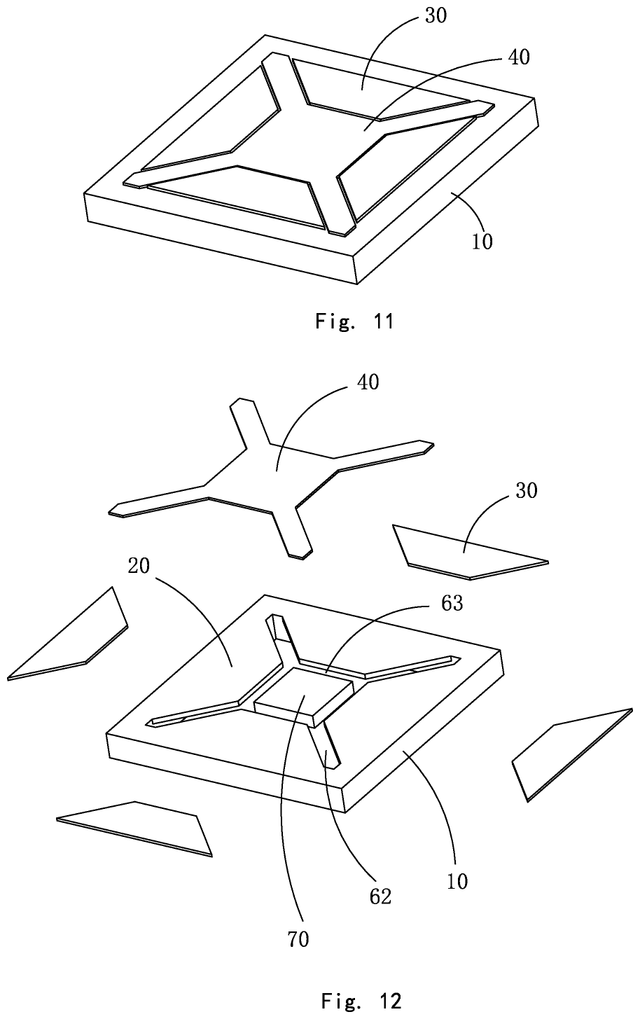

As shown in FIGS. 11-12, the difference between embodiment five and embodiment four is that the flexible connector 40 has a flat structure, and the suspension end 22 and the weight 70 are completely spaced apart. There is no connection structure between the two. Therefore, both ends of the third slit 63 are connected to a second slit 62. At this time, the weight 70 in the middle serves to increase the strength of the flexible connector 40.

It should be understood that, in all embodiments, when the flexible connector 40 has a non-flat structure, the MEMS acoustic sensor also includes a sealer 80 as shown in FIG. 4. The sealer 80 fixes the flexible part connector 40 to one end of the base 10 for sealing, so that a completely sealed structure can be achieved.

Compared with the related technology, the suspension end of the piezoelectric functional layer in the MEMS acoustic sensor of the present invention is separated from the base or adjacent suspension ends to form a slit. Use the flexible connector piezoelectric functional layer's suspension end and base and/or connect two adjacent suspension ends to completely cover the slit. The flexible connector can be arranged along the slit, and it is arranged at a distance from the piezoelectric functional layer and does not need to be formed on the electrode of the piezoelectric functional layer. This effectively improves the flexible connector's limitation on the area of the piezoelectric functional layer. The effective vibration area of the diaphragm is increased, thereby making the acoustic performance better.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A MEMS acoustic sensor, comprising:
a base with a cavity;
a plurality of structural layers fixed on the base, each comprising a fixed end fixed to the base and a suspension end extending from the fixed end for being suspended above the cavity, the suspension end being spaced from the base for forming a slit;
a piezoelectric functional layer on the suspension end; and
a flexible connector completely covering the slit; wherein a Young's modulus of the flexible connector is smaller than a Young's modulus of the structural layer.

2. The MEMS acoustic sensor as described in claim 1, wherein the fixed end is fixed to one side of the base along a long axis or along a short axis; the suspension end is oppositely spaced from the other three sides of the base to form the slit; the flexible connector connects the suspension end and the base and completely covers the slit.

3. The MEMS acoustic sensor as described in claim 1, wherein an amount of the structural layer is two; the fixed end is fixed on each side of the base opposite to each other; the two suspension ends extend oppositely and are spaced apart from each other; the suspension end is oppositely spaced from the base to form a first slit, and the suspension end is oppositely spaced to form a second slit; the first slit is in communication with the second slit.

4. The MEMS acoustic sensor as described in claim 3, wherein, the flexible connector includes a first connector that completely covers the first slit and a second connector that completely covers the second slit; the first connector connects the suspension end and the base; the second connector connects the two adjacent suspension ends; the first connector and the second connector are connected with each other.

5. The MEMS acoustic sensor as described in claim 1, wherein an amount of the structural layer is four; the fixed end is fixed on each side of the base; the four suspension ends are arranged at intervals; the slit extends along two diagonals of the base.

6. The MEMS acoustic sensor as described in claim 5, wherein the structural layer is fixed to the base along one side of the hypotenuse to form the fixed end; the right-angle tips of the four structural layers are oppositely spaced apart.

7. The MEMS acoustic sensor as described in claim 1 further comprising a weight accommodated in the cavity and being apart from the base; the base and the weight are concentric rectangles; four structural layers are arranged; one fixing part is fixed on each side of the base; the suspension end extends from the fixing portion toward the weight to be spaced apart from the weight; the slit includes a second slit formed by two adjacent suspension ends and a third slit between the suspension end and the weight; the second slit extends from the corner position of the weight to the corner position of the base.

8. The MEMS acoustic sensor as described in claim 7, wherein, the flexible connector includes a second connector covering the second slit and a third connector covering the third slit; the four third connectors are connected end to end to form a ring-shaped rectangle; the second connector is fixed at the junction of two adjacent third connectors.

9. The MEMS acoustic sensor as described in claim 7, wherein, the flexible connector is in the shape of a flat plate.

10. The MEMS acoustic sensor as described in claim 7, wherein, the flexible connector includes a first fixed part fixed to the base, a second fixed part fixed to the suspension end, and an flexible part connecting the first fixed part and the second fixed part; the section of the flexible part along the vibration direction of the structural layer is arc, triangle, or rectangle; the structural layer further includes an flexible connection structure that extends from the end of the suspension end away from the fixed end to the weight to be fixed to the weight; the flexible connection structure is located at both ends of the suspension end close to the second slit.
